(19) United States
(12) Patent Application Publication
(10) Pub. No.: US 2004/0114771 A1
(43) Pub. Date: Jun. 17, 2004

(54) Multimedia system with pre-stored equalization sets for multiple vehicle environments

(76) Inventors: Mitchell Vaughan, Maldon (GB); Stephen James Adams, Chelmsford (GB); Karl Westhead, Chelmsford (GB); Alan Johnson, Basildon (GB)

Correspondence Address: MACMILLAN, SOBANSKI & TODD, LLC, ONE MARITIME PLAZA-FOURTH FLOOR, 720 WATER STREET, TOLEDO, OH, 43604, US

(21) Appl. No.: 10/318,481

(22) Filed: Dec. 12, 2002

(51) Int. Cl. H04B 1/00; H03G 5/00

(52) U.S. Cl. 381/86; 381/103

(57) ABSTRACT

A multi-channel audio system can be installed into any of a plurality of acoustically unique vehicle environments. A digital signal processing system for processing source audio signals generates a plurality of audio output signals to be coupled to audio transducers, wherein the digital signal processing system includes a multi-channel equalization filter. An equalization coefficient memory stores a plurality of equalization characteristic sets, each equalization characteristic set corresponding to a respective one of the vehicle environments. A controller couples a selected one of the equalization characteristic sets to the multi-channel equalization filter in response to a vehicle environment identification signal.

### CROSS REFERENCE TO RELATED APPLICATIONS

Not Applicable.

### STATEMENT REGARDING FEDERALLY SPONSORED RESEARCH

Not Applicable.

### BACKGROUND OF THE INVENTION

The present invention relates in general to automotive multimedia systems, and, more specifically, to providing customized acoustic frequency response equalization for a variety of vehicle models and interior acoustic environments.

Nearly all automotive vehicles (i.e., cars and trucks) have a radio or some kind of multimedia audio system installed. However, a vehicle interior is far from an ideal acoustic environment. Because of the relatively small volume of the interior, the irregular shape of the interior space, acoustic properties of reflective surfaces and obstructions in the interior, and the non-optimal locations available for mounting of loudspeakers, the frequency response characteristic of reproduced sound as heard at a listening position (e.g., the driver's seat) is distorted.

Equalization is a known technique wherein the frequency response and/or time delay of each individual audio channel is modified electronically to compensate the reproduced audio characteristics in order to provide a more desirable frequency spectrum. The desired spectrum is not necessarily flat. In many automotive applications, it is desirable to provide relatively greater gain at bass frequencies (i.e., bass boost) in order to mask road and engine noise. Equalization comprises a reduction of audio frequencies which are overemphasized by the vehicle's acoustic environment above a desired spectral curve.

The re-shaping of the spectral response as heard by the listener is obtained using an equalization filter, typically implemented within a digital signal processor (DSP). The frequency-gain curve of a particular filter is determined by the set of filter coefficients utilized in a multi-tapped, recursive digital filter structure such as a finite impulse response (FIR) or infinite impulse response (IIR) filter.

It is known that by adjusting the set of filter coefficients, an equalization filter can be adapted to different vehicle interiors. As shown in U.S. Pat. No. 5,617,480, a set of coefficients can be determined for a particular vehicle model or a particular vehicle environment using a test vehicle in a sound laboratory and the resulting equalization parameters can be saved and then programmed into the memory of an audio system to be installed in the same vehicle environment as the test vehicle.

An equalization filter can be designed in advance as part of the basic design of an audio system to be used in a single vehicle environment, but this requires an automobile manufacturer to maintain different audio system end items (i.e., with each end item being installed into a distinct vehicle model and interior configuration). In an alternative taught by U.S. Pat. No. 5,617,480, the audio system can be designed to have an electrically programmable memory (e.g., an EEPROM) and the equalization filter coefficients are downloaded into the memory at the time that the audio system is installed into a vehicle at the vehicle assembly plant. Thus, an amount of field-programmable memory is set aside to hold the coefficients that are actually used by the equalization filter during system operation. A large number of audio systems can be manufactured in advance and then any one of them can be installed into any vehicle environment after that environment has been characterized in a sound lab for a test vehicle (i.e., so that an appropriate set of filter coefficients can be downloaded into the audio system).

Programming of filter coefficients in a vehicle assembly plant which makes many different models of vehicles and/or different interior configurations of one vehicle requires the assembly plant to maintain separate electronic files for downloading, as well as the equipment and procedures for achieving the downloads (which are subject to breakdowns or errors). Different equalization curves are typically required for different configurations of the same vehicle model such as different interior trim material (e.g., cloth, vinyl, or leather), body style (e.g., 2-door, 3-door, 4-door, and 5-door), drive configuration (e.g., left-hand drive or right-hand drive), and speaker configuration (e.g., with subwoofer or without subwoofer). The resulting complexity of 1) supplying and inventorying numerous different audio systems (which may even have identical exterior appearance), or 2) maintaining numerous EQ coefficient sets and downloading all the coefficients without error, are undesirable from a manufacturing standpoint.

### SUMMARY OF THE INVENTION

The present invention has the advantage of providing a single model or end item for an audio system which has customizable equalization without requiring downloading of an EQ coefficient set at the vehicle assembly plant. According to the present invention, EQ coefficient sets for a number of different vehicle models and/or interior configurations of each model are stored in the audio system. Manual and automatic mechanisms are provided for selecting the appropriate one of the stored coefficient sets based on the vehicle model, trim, body style, and/or other identifiers of the vehicle interior environment.

In one aspect of the invention, a multi-channel audio system is provided for installation into any of a plurality of acoustically unique vehicle environments. A digital signal processing system for processing source audio signals generates a plurality of audio output signals to be coupled to audio transducers, wherein the digital signal processing system includes a multi-channel equalization filter. An equalization coefficient memory stores a plurality of equalization characteristic sets, each equalization characteristic set corresponding to a respective one of the vehicle environments. A controller couples a selected one of the equalization characteristic sets to the multi-channel equalization filter in response to a vehicle environment identification signal.

### BRIEF DESCRIPTION OF THE DRAWINGS

FIG. 1 depicts a test/measurement system for characterizing an EQ coefficient set for an audio system operating in a particular vehicle interior environment.

FIG. 2 is a table showing acoustically unique vehicle environments for which a single model of audio system is configurable.

FIG. 3 is a block diagram showing a vehicle multiplex system and an audio system according to the present invention.

FIG. 4 is a flowchart showing one preferred method of the present invention.

### DETAILED DESCRIPTION OF PREFERRED EMBODIMENTS

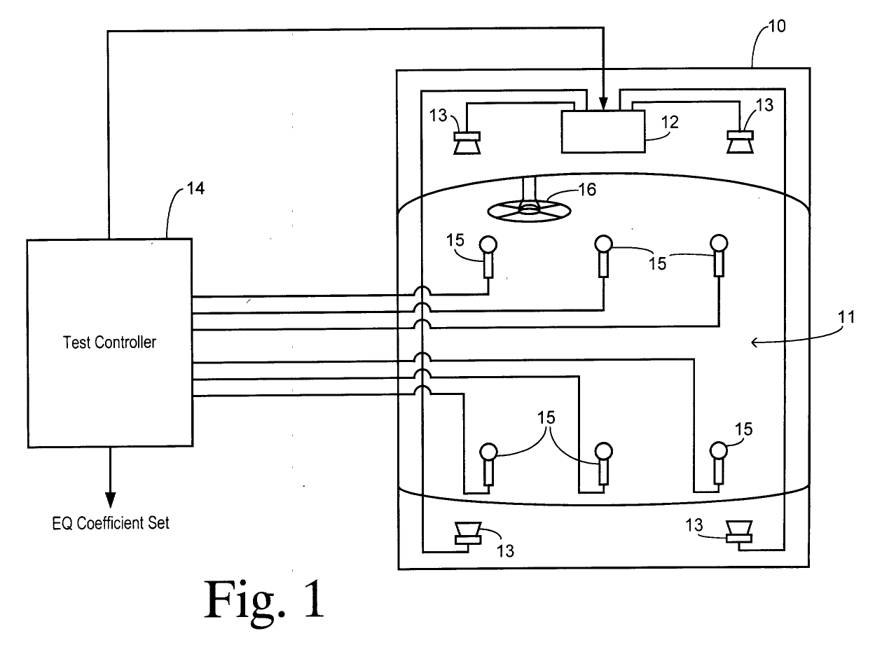

Referring to FIG. 1, a vehicle 10 has an interior space 11 providing an acoustic vehicle environment in which a multimedia audio system operates. The audio system includes a predetermined model or a main unit or head unit 12 connected to a plurality of speakers 13. An early production or prototype unit of a particular vehicle model and interior configuration is tested in a sound lab to determine a set of EQ coefficients to be used when the head unit is fitted to the vehicle model/configuration. For purposes of the test, a test controller 14 is connected to head unit 12 and to a bank of microphones 15 deployed in interior space 11. An audio test signal (e.g., pink noise) is coupled to head unit 12 for reproduction over speakers 13. Microphones 15 pick up the resulting sound at predetermined positions in interior space 11 and the microphone signals are analyzed to determine the frequency spectrum being produced. Coefficients for an equalization filter in head unit 12 are interactively adjusted until a desired spectral curve is sensed by microphones 15. The final set of coefficients for producing the desired equalization is stored for later inclusion in general production audio systems intended to be used with the target vehicle model/configuration.

The characterization process shown in FIG. 1 may need to be conducted for several configurations of one vehicle model since the different configurations may have dramatically different effects on the acoustic behavior of the vehicle environment. Specifically, changes in the materials of interior trim surfaces (such as cloth, vinyl, or leather seats), body styles (e.g., as determined by the number of doors and/or a hatchback door), and configuration of the loudspeakers (e.g. number and types of speakers when a single vehicle model has more than one speaker configuration available) can all create acoustic differences that require difference equalization coefficient sets. In addition, the drive side of a vehicle (i.e., the side of the vehicle on which steering wheel 16 is installed) can be taken into consideration since equalization is typically optimized for the listening location of the driver. At the end of a test for a particular vehicle model/interior configuration, the corresponding EQ coefficient set is output from test controller 14.

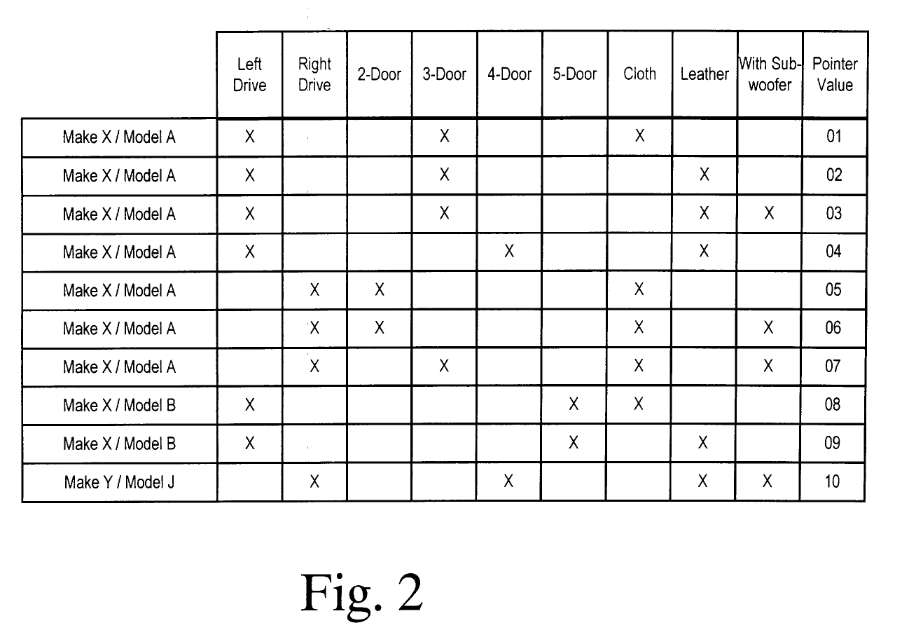

As shown in the table of FIG. 2, a plurality of vehicles and their corresponding interior configurations that acoustically require a unique equalization coefficient set are correlated to respective pointer values that identify the position in the audio system memory of the appropriate coefficient set. Each column shows an element of the vehicle configurations that give rise to and identify the unique acoustic environments. Left-hand or right-hand drive is important (if a particular model is available in both) to determine which listening position the sound field should be optimized for. The number of doors determines a body style, each body style typically having a differently shaped interior space and/or speaker placement. Interior trim material, such as cloth, leather, or vinyl, provide different sound reflection and require different EQ coefficient sets if a particular model is available with different trim materials. If the vehicle is made with optional speaker configurations (e.g., an optional subwoofer) then corresponding EQ coefficient sets must be provided.

The EQ coefficient set for each respective model/configuration is identified by a pointer value or index value listed in the last column of the table. The information in the table can be used by a vehicle assembler to determine which coefficient set (i.e., pointer value) should be selected when installing the model of audio system in one of the models/configurations of the vehicles.

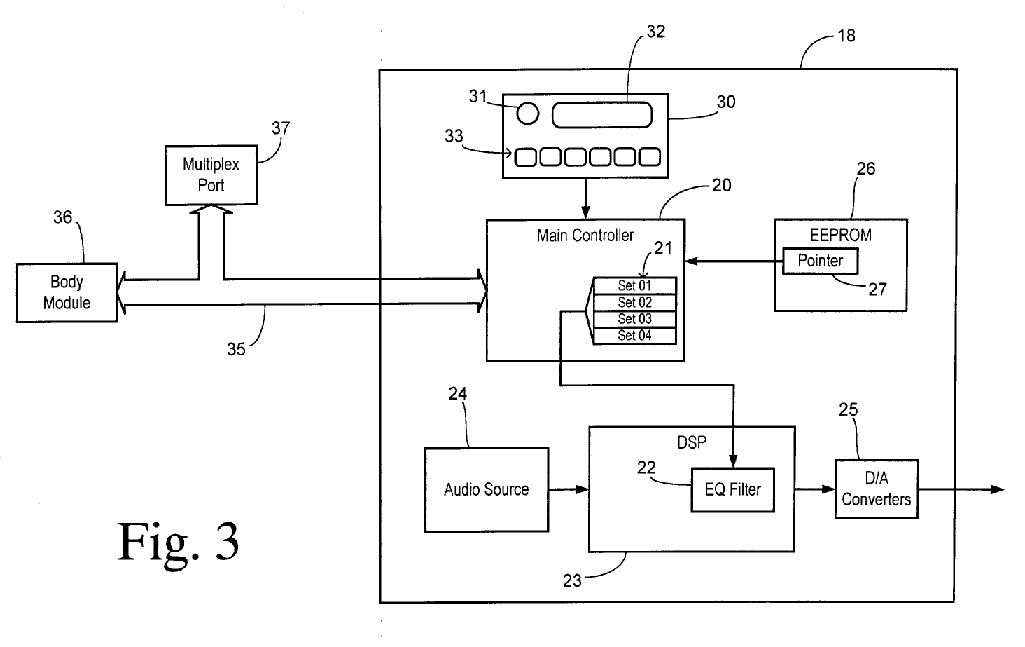

FIG. 3 shows a regular production unit of the audio system main unit 18. A main controller 20 (e.g., a programmable microcontroller) coordinates audio system operation and includes a read-only memory (ROM) 21 which stores a plurality of EQ coefficient sets in a data array. When the audio system is turned on, an EQ coefficient set is selected and transferred to an EQ filter 22 in a digital signal processor (DSP) 23. Audio signals from an audio source 24 (e.g., a radio tuner, CD player, MP3 player, or cassette tape player) are processed by DSP 23. For an analog source, an analog-to-digital (A/D) converter (not shown) is used to couple the audio signal to DSP 23. Audio processing in DSP 23 includes equalizing the audio signal in filter 22. The resulting equalized audio signals are converted to analog signals by digital-to-analog (D/A) converters 25 and sent to the audio speakers (not shown).

A vehicle environment identification signal 27 (i.e., the pointer to the appropriate EQ coefficient set) is stored in a non-volatile, programmable (i.e., rewritable) memory 26 which may be comprised of an electrically erasable programmable read only memory (EEPROM). Memory 26 may be internal to controller 20 or may be a separate component.

In order to set a pointer value manually, a person may interact with the audio system using controls on a front control panel 30 of main unit 18, for example. Panel 30 includes an on/off volume control knob 31, an information display 32, and control buttons 33. In a preferred embodiment, main controller 20 is programmed to provide a hidden menu which is accessed by depressing a pair of control buttons 33 for a predetermined time (e.g., two seconds). In the hidden menu, the available pointer values are displayed. Using predetermined control buttons (e.g., a tune up/down rocker switch for radio tuning), the user scrolls through a list of pointer values and indicates a selection using another one of control buttons 33. Controller 20 stores the indicated pointer value in EEPROM 26 and reverts to normal operation of display 32. The hidden menu may be contained in the self-test procedure already present in some currently manufactured audio systems.

A pointer value can also be set via a multiplex bus 35 that interconnects a multiplex bus interface in main controller 20 with a body module 36 and/or a direct multiplex port 37. A multiplex message can be sent to main controller 20 either containing the desired pointer value or containing information that can be correlated to a pointer value by main controller 20. For example, body module 36 may be a driver's door module or other conventional module communicating on multiplex bus 35 which stores information about trim material, body style, and drive configuration of the vehicle in which it and the audio system are installed. When the audio system goes through an initialization procedure each time that it is newly connected to main battery power, it requests the information from body module 36 via multiplex messages (while the audio system detects the speaker configuration itself). Main controller 20 would contain a stored version of the table of FIG. 2 and it compares the multiplex information with the table to determine and store the pointer value corresponding to the appropriate EQ coefficient set.

Instead of the audio system requesting the information from another module, the information could be sent without a request either automatically or manually via an external multiplex port 37 (e.g., which is conventionally used for vehicle diagnostics and programming). This programming of the pointer value could be performed during end-of-line testing in a vehicle assembly plant, for example. Again, the information passed to the audio system may comprise the pointer value itself or information that defines the vehicle environment in terms of vehicle model, drive configuration, trim, body style, and/or speaker configuration. By using the vehicle environment information in the multiplex communication, the need to provide pointer value information to the vehicle assembly plant is avoided, thereby simplifying the plant logistics.

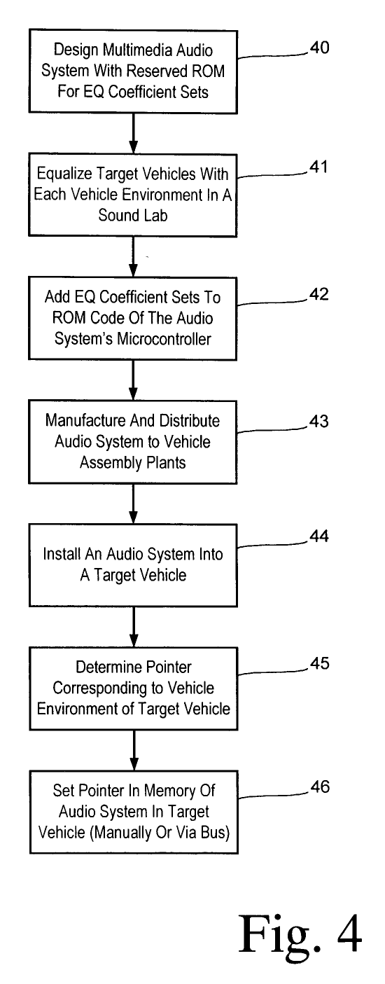

A preferred method of the invention is shown in FIG. 4. In step 40, the hardware and operating software of a multimedia audio system are designed. The design includes an equalization filter which accepts different coefficient sets to provide different equalization curves. The ROM code requirements of the design include the reservation of memory space to permanently retain a plurality of EQ coefficient sets. In step 41, a plurality of target vehicles into which the audio system can be installed are analyzed in a sound laboratory. Preferably, the analysis uses early production or prototype vehicles and a prototype audio system installed in the test target vehicles that are as close as possible to their final production states. Each vehicle environment is equalized and the corresponding EQ coefficient set is determined.

In step 42, all the EQ coefficient sets from all the target vehicle environments are added to the ROM code of the audio system's microcontroller in the reserved memory space. After initial release of the audio system for production, additional EQ coefficient sets could be added to subsequently manufactured units of the audio system via software updates.

In step 43, the single model of audio system containing all the EQ coefficient sets in memory is mass produced and distributed to vehicle assembly plants. A unit of the audio system is installed into a target vehicle in step 44.

In step 45, the appropriate pointer (i.e., a vehicle environment identification signal) corresponding to the vehicle environment of the target vehicle is determined. In step 46, the pointer is set in the field programmable memory (e.g., EEPROM) of the audio system in each individual target vehicle. As previously described, the setting of the pointer can be performed manually from the control panel or can be accomplished over a multiplex connection. Even if performed over the multiplex bus, the capability to select a pointer value using the audio system control panel should be maintained to facilitate servicing of the audio system. In addition, more than one equalization curve could be configured for a single vehicle environment for special needs.

In a further embodiment, the audio system may also contain EQ coefficient sets that approximate predetermined generic vehicle environments (e.g., pickup truck, small sedan, etc.) instead of specific target vehicles, so that the audio system can achieve reasonable performance if installed into a vehicle that was not characterized in a sound lab.

What is claimed is:

1. A multi-channel audio system for installation into any of a plurality of acoustically unique vehicle environments, comprising:
a digital signal processing system for processing source audio signals to generate a plurality of audio output signals to be coupled to audio transducers, said digital signal processing system including a multi-channel equalization filter;
an equalization coefficient memory storing a plurality of equalization characteristic sets, each equalization characteristic set corresponding to a respective one of said vehicle environments; and
a controller for coupling a selected one of said equalization characteristic sets to said multi-channel equalization filter in response to a vehicle environment identification signal.

2. The audio system of claim 1 wherein said vehicle environment identification signal signifies a particular model of vehicle.

3. The audio system of claim 2 wherein said vehicle environment identification signal signifies a particular interior trim material type.

4. The audio system of claim 2 wherein said vehicle environment identification signal signifies a particular body style of said particular model of vehicle.

5. The audio system of claim 2 wherein said vehicle environment identification signal signifies a particular drive configuration of said particular model of vehicle.

6. The audio system of claim 2 wherein said vehicle environment identification signal signifies a particular transducer configuration among a plurality of predetermined configurations.

7. The audio system of claim 1 further comprising a plurality of user control elements for generating said vehicle environment identification signal in response to manual activation of said user control elements.

8. The audio system of claim 7 wherein said manual activation accesses a hidden menu of said audio system for designating said vehicle environment identification signal.

9. The audio system of claim 8 wherein said hidden menu is accessed by activating a predetermined combination of said user control elements simultaneously.

10. The audio system of claim 1 further comprising a multiplex bus interface for communicating with a multiplex bus in said vehicle environment, wherein said vehicle environment identification signal is transmitted to said audio system via said multiplex bus.

11. The audio system of claim 10 wherein said vehicle environment identification signal is transmitted to said audio system at a vehicle assembly plant during end-of-line testing of a vehicle into which said audio system is installed.

12. The audio system of claim 10 wherein said controller initializes said audio system upon initial connection to a source of electrical power in a vehicle in which said audio system is installed, and wherein said controller sends a request for said vehicle environment identification signal to another electronic module connected to said multiplex bus during said initializing.

13. The audio system of claim 1 further comprising an electronically programmable memory for storing said vehicle environment identification signal.

14. A method of operating a single model of automotive audio system in a plurality of unique vehicle environments, said method comprising the steps of:
determining respective sets of equalization coefficients by which said single model of audio system provides respective equalized audio reproduction in each of said plurality of unique vehicle environments when said respective set of equalization coefficients is loaded into an equalization filter in said single model of audio system;
manufacturing a plurality of said single model of audio system, each of said manufactured audio systems having each of said respective sets of equalization coefficients stored therein;
installing a particular one of said manufactured audio systems into a particular vehicle, said particular vehicle having one of said unique vehicle environments;
setting a pointer in said particular one of said manufactured audio systems for identifying a particular one of said respective sets of equalization coefficients corresponding to said particular vehicle; and
each time said particular audio system is turned on, then transferring said particular one of said respective sets of equalization coefficients identified by said pointer to said equalization filter.

15. The method of claim 14 wherein said unique vehicle environments include a plurality of standard production vehicle models.

16. The method of claim 15 wherein said unique vehicle environments include a plurality of predetermined interior trim material types within a single of said standard production vehicle models.

17. The method of claim 15 wherein said unique vehicle environments include a plurality of predetermined body styles within a single of said standard production vehicle models.

18. The method of claim 17 wherein said predetermined body styles include a two-door body style, a three-door body style, and a four-door body style.

19. The method of claim 17 wherein said unique vehicle environments include a plurality of predetermined drive configurations within a single of said standard production vehicle models, said predetermined drive configurations including a left-hand drive configuration and a right-hand drive configuration.

20. The method of claim 17 wherein said unique vehicle environments include a plurality of predetermined transducer configurations within a single of said standard production vehicle models.

21. The method of claim 14 wherein said step of setting said pointer comprises generating a vehicle environment identification signal in response to manual activation of user control elements on said audio system.

22. The method of claim 21 wherein said manual activation accesses a hidden menu of said audio system for designating said vehicle environment identification signal.

23. The method of claim 22 wherein said hidden menu is accessed by activating a predetermined combination of said user control elements simultaneously.

24. The method of claim 21 wherein said audio system further comprises a multiplex bus interface for communicating with a multiplex bus in said particular vehicle, and wherein said vehicle environment identification signal is transmitted to said audio system via said multiplex bus.

25. The method of claim 24 wherein said vehicle environment identification signal is transmitted to said audio system at a vehicle assembly plant during end-of-line testing of said particular vehicle into which said audio system is installed.

26. The method of claim 24 wherein said audio system is initialized upon initial connection to a source of electrical power in said particular vehicle, and wherein said audio system sends a request for said vehicle environment identification signal to another electronic module connected to said multiplex bus during said initializing.
